(19) United States
(12) Patent Application Publication
(10) Pub. No.: US 2017/0090295 A1
(43) Pub. Date: Mar. 30, 2017

(54) EXPOSURE APPARATUS AND EXPOSURE METHOD

(71) Applicant: Kabushiki Kaisha Toshiba, Minato-ku (JP)

(72) Inventor: Shinji ETO, Yokkaichi (JP)

(73) Assignee: Kabushiki Kaisha Toshiba, Minato-ku (JP)

(21) Appl. No.: 14/983,713

(22) Filed: Dec. 30, 2015

(30) Foreign Application Priority Data
Sep. 29, 2015 (JP) 2015-191206

(51) Int. Cl. G03F 7/20

(52) U.S. Cl. CPC G03F 7/707; G03F 7/7015; G03F 7/20

(57) ABSTRACT

According to one embodiment, an exposure apparatus comprises a stage, a projection optical system, and a gas sucking device. A wafer is mounted on the stage. The projection optical system projects exposure light onto the wafer. The gas sucking device sucks gas above the wafer in directions of the outer edge of the wafer.

### CROSS-REFERENCE TO RELATED APPLICATIONS

This application is based upon and claims the benefit of priority from Japanese Patent Application No. 2015-191206, filed on Sep. 29, 2015; the entire contents of which are incorporated herein by reference.

### FIELD

Embodiments described herein relate generally to an exposure apparatus and an exposure method.

### BACKGROUND

When a resist film coated on a wafer is exposed, outgas may originate from the resist film. This outgas rises to reach the projection optical system of the exposure apparatus and thus may inflict damage on the projection optical system of the exposure apparatus.

### BRIEF DESCRIPTION OF THE DRAWINGS

FIG. 1 is a perspective view showing schematically the configuration of an exposure apparatus according to a first embodiment;

FIG. 2 is a cross-sectional view showing schematically the configuration of the exposure apparatus according to the first embodiment;

FIG. 3 is a perspective view showing schematically the configuration of an exposure apparatus according to a second embodiment; and

FIGS. 4A and 4B are cross-sectional views showing wafer transfer operation of the exposure apparatus according to the second embodiment.

### DETAILED DESCRIPTION

In general, according to one embodiment, an exposure apparatus comprises a stage, a projection optical system, and a gas sucking device. A wafer is mounted on the stage. The projection optical system projects exposure light onto the wafer. The gas sucking device sucks gas above the wafer in directions of the outer edge of the wafer.

Exemplary embodiments of exposure apparatuses will be explained below in detail with reference to the accompanying drawings. The present invention is not limited to the following embodiments.

### FIRST EMBODIMENT

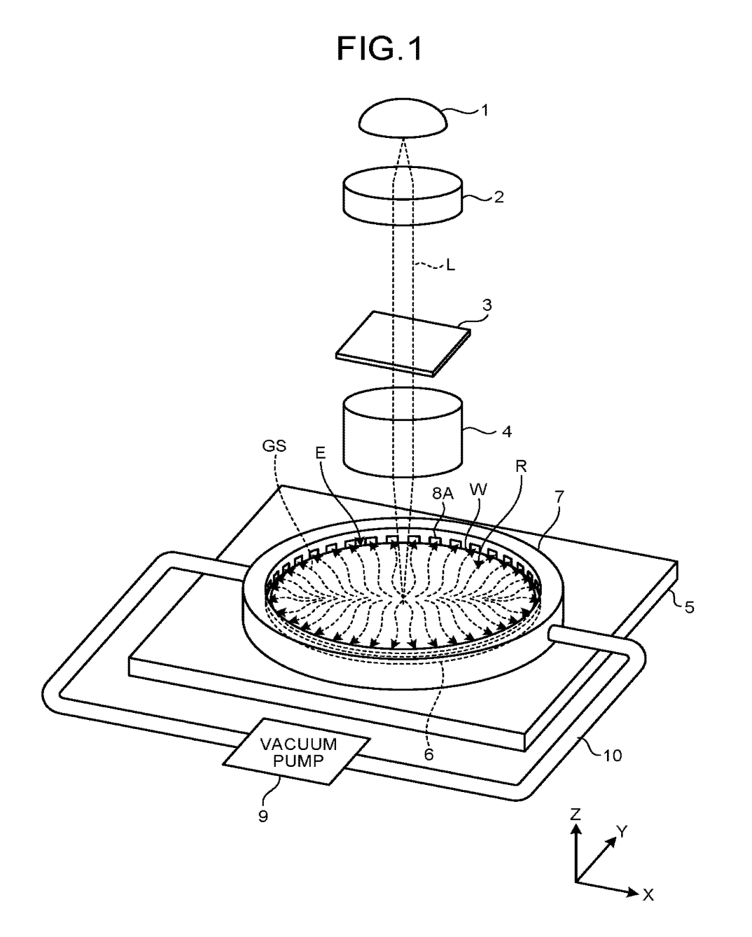

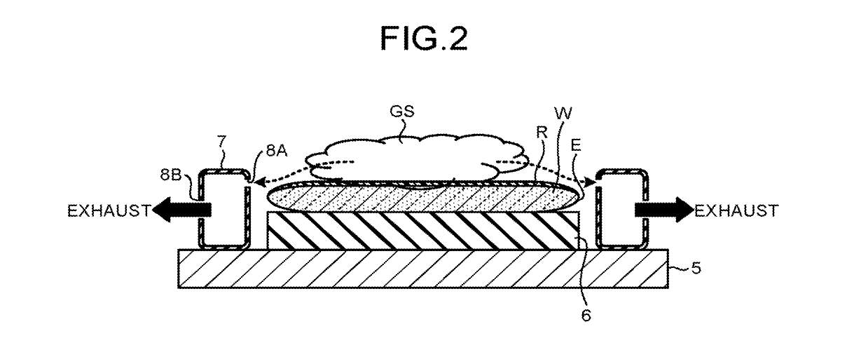

FIG. 1 is a perspective view showing schematically the configuration of an exposure apparatus according to the first embodiment, and FIG. 2 is a cross-sectional view showing schematically the configuration of the exposure apparatus according to the first embodiment.

In FIGS. 1 and 2, the exposure apparatus is provided with a light source 1 that emits exposure light L, an illumination lens 2 that irradiates the exposure light L onto a mask 3, a projection optical system 4 that projects the exposure light L having passed through the mask 3 onto a wafer W, and a stage 5 on which to mount a wafer W. The material of the wafer W may be a semiconductor such as Si, ceramic such as glass, or a magnetic material. A chuck 6 to stick the wafer W thereto by suction is provided on the stage 5. A resist film R is coated on the wafer W. The wafer W on the stage 5 can be placed on an XY plane. Further, a gas sucking device 7 to suck outgas GS above the wafer N is provided on the stage 5. The gas sucking device 7 is connected to a vacuum pump 9 via an exhaust pipe 10.

The gas sucking device 7 can suck gas above the wafer W in directions of the outer edge E of the wafer W. As gas above the wafer W, outgas GS emitted from the resist film R can be cited. As the outgas GS emitted from the resist film R, for example, an organic substance such as hydrocarbon can be cited. Letting a Z direction be the height direction with respect to an XY plane, the gas sucking device 7 can suck outgas GS so as to have part moving in an X direction and/or Y direction of the XY plane substantially without part moving in the Z direction. The gas sucking device 7 can be placed on the stage 5 to surround the outer edge E of the wafer W. Thus, the gas sucking device 7 can suck outgas GS in substantially all directions of the outer edge E of the wafer W. The gas sucking device 7 can be configured to be in a ring shape having an inner diameter larger than the diameter of the wafer W.

Here, the gas sucking device 7 is provided with intake holes 8A along the inner perimeter surface of the gas sucking device 7. Exhaust holes 8B are provided in the outer perimeter surface of the gas sucking device 7. In this case, the intake holes 8A may be placed along the inner perimeter surface of the gas sucking device 7 at predetermined intervals or consecutively. The exhaust holes 8B are connected to the exhaust pipe 10.

In the exposure step of photolithography, the wafer W coated with the resist film R is transferred onto the chuck 6. Then the chuck 6 attracts the wafer W by suction, thereby fixing the wafer W on the chuck 6. When the wafer W is fixed on the chuck 6, outgas GS is being emitted from the resist film R. At this time, if the vacuum pump 9 is made to operate, the gas sucking device 7 sucks outgas GS above the wafer W in directions of the outer edge E of the wafer W. Then the outgas GS is sucked into the gas sucking device 7 through the intake holes 8A placed opposite the outer edge of the wafer W and discharged into the outside of the stage 5 through the exhaust holes 8B. The suction of outgas GS by the gas sucking device 7 is preferably started before outgas GS emitted from the resist film R reaches the projection optical system 4. For example, the suction of outgas GS may be started at the same time that the wafer W is transferred onto the chuck 6, or the suction of outgas GS may be started before the wafer W is transferred onto the chuck 6. Or the suction of outgas GS may be started at the same time that the wafer W is attracted onto the chuck 6 by suction.

When the suction of outgas GS starts, exposure light L is emitted from the light source 1. The exposure light L is converted by the illumination lens 2 into parallel light and then is incident on the mask 3. The exposure light L having passed through the mask 3 is projected by the projection optical system 4 onto the wafer W, so that the resist film R is exposed thereto.

At this time, while outgas GS above the wafer W is being sucked in directions of the outer edge E of the wafer W, the resist film R is exposed via the projection optical system 4. Thus, outgas GS can be prevented from rising so high as to reach the projection optical system 4, so that damage to the projection optical system 4 can be prevented.

Further, because outgas GS can be prevented from sticking to the projection optical system 4, there is no need for maintenance work to wipe outgas GS from the projection optical system 4, so that operation loss can be reduced.

Yet further, by reducing the amount of outgas GS above the wafer W, reduction in the illumination of the exposure light L above the wafer W can be suppressed, so that throughput can be improved. Still further, by reducing the amount of outgas GS above the wafer W, variation in the illumination of the exposure light L above the wafer W can be suppressed, so that variation in within-a-shot dimensions of a resist pattern can be reduced.

Although the above embodiment describes the case where a projection lens is used for the projection optical system 4 of the exposure apparatus, with an EUV (Extreme Ultra Violet) exposure apparatus or the like, a projection mirror may be used for the projection optical system 4.

Further, although the above embodiment describes the method which uses the gas sucking device 7 to suck outgas GS emitted from the resist film R, the gas sucking device 7 may be used to suck other gas above the wafer W other than outgas GS. For example, in the case where F₂ laser light having a wavelength of 157 nm is used as the exposure light L, oxygen, moisture, and the like in air act as gases opaque to F₂ laser light. Hence, in order to remove such opaque gases from space above the wafer W at exposure, the gas sucking device 7 may be used.

### SECOND EMBODIMENT

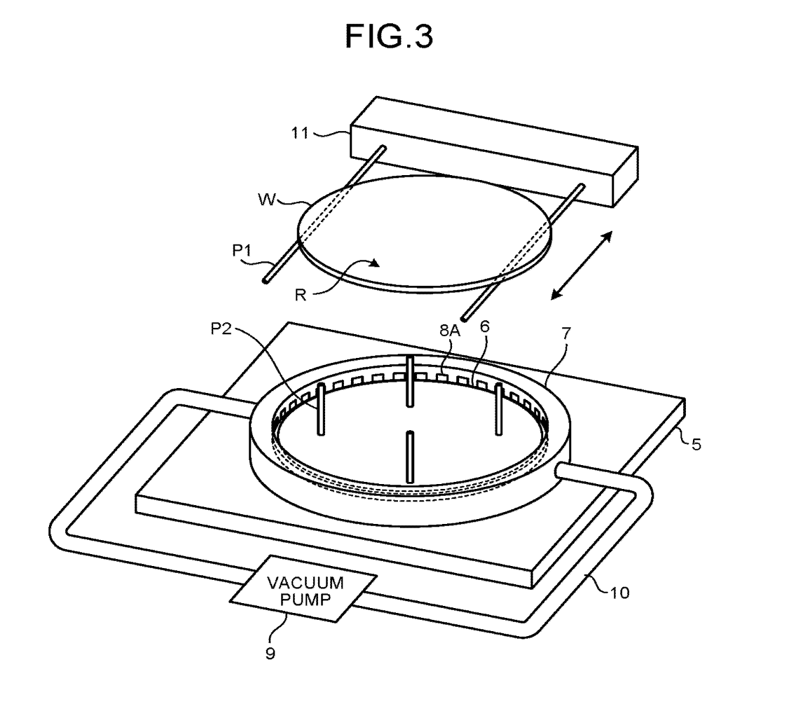

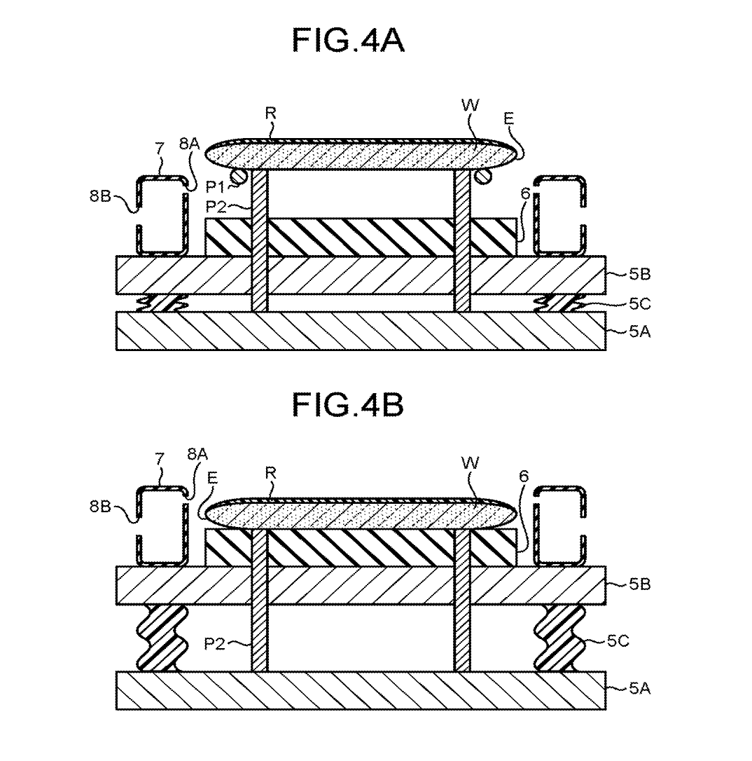

FIG. 3 is a perspective view showing schematically the configuration of an exposure apparatus according to the second embodiment, and FIGS. 4A and 4B are cross-sectional views showing wafer transfer operation of the exposure apparatus according to the second embodiment.

In the configuration of FIG. 3, pins P2 are added to the exposure apparatus of FIG. 1. The pins P2 can be held to stand pointing in the Z direction on the stage 5. The pins P2 can support a wafer W on their ends. A carrier device to transfer the wafer W over the stage 5 is provided attendant to the exposure apparatus. This carrier device is provided with pins P1 to hold the wafer W and a holder 11 to hold the pins P1 horizontally. The holder 11 can move horizontally. The pins P1 can support the wafer W on their sides. The pins P1, P2 can be placed such that the pins P1, P2 do not touch when the wafer W is in contact with the pins P1, P2.

As shown in FIGS. 4A and 4B, the stage 5 is provided with a coarse movement stage 5A and a fine movement stage 5B, which can move up and down. The fine movement stage 5B is placed above the coarse movement stage 5A. The fine movement stage 5B and the coarse movement stage 5A are connected via elastic bodies 5C. As the elastic body 5C, for example, a spring or the like that can stretch and contract along the Z direction can be used. In this case, the fine movement age 5B can move up and down relative to the coarse movement stage 5A. The fine movement stage 5B can be made higher in position accuracy than the coarse movement stage 5A. The position of the fine movement stage 5B can be controlled with accuracy on the order of a nanometer.

The pins P2 can be held extending through the chuck 6 and the fine movement stage 5B on the coarse movement stage 5A, in this case, the pins P2 can be fixed on the coarse movement stage 5A. The chuck 6 and the fine movement stage 5B can move up and down relatively with respect to the pins P2.

When the wafer W is transferred over the chuck 6, the wafer W is held on the pins P1 as shown in FIG. 3. Then, as shown in FIG. 4A, the coarse movement stage 5A and the fine movement stage 5B are put in such a positional relation that the ends of the pins P2 held on the coarse movement stage 5A protrude up through the chuck 6 to be at a position higher than the top surface of the gas sucking device 7. Then the pins P1 are made to advance so as to transfer the wafer W over the stage 5 to be mounted on the ends of the pins P2. Then the pins P1 are moved back to be withdrawn from above the stage 5. After the pins P1 are withdrawn from above the stage 5, the coarse movement stage 5A holding the pins P2 is moved down, or the fine movement stage 5B is raised relative to the pins P2, so that the ends of the pins P2 are positioned lower than the surface of the chuck 6, and thus the wafer W is held on the chuck 6. At this time, when the fine movement stage 5B is raised relatively with respect to the coarse movement stage 5A holding the pins P2 in a Z-direction position relation, the gas sucking device 7 provided on the fine movement stage 5B is raised relatively with respect to the wafer W mounted on the ends of the pins P2, and thus the gas sucking device 7 can be placed to surround the outer edge E of the wafer W while the wafer W is held on the chuck 6.

Here, because the Z-direction position relation between the pins P2 and the gas sucking device 7 is made adjustable, the wafer W can be transferred over the chuck 6 without interfering with the gas sucking device 7 even where the gas sucking device 7 is placed to surround the outer edge E of the wafer W.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An exposure apparatus comprising:
a stage on which to mount a wafer;
a projection optical system that projects exposure light onto the wafer; and
a gas sucking device that sucks gas above the wafer in directions of the outer edge of the wafer.

2. The exposure apparatus of claim 1, wherein the wafer is placed on an XY plane, and
wherein the gas sucking device sucks the gas so as to have part moving in an X direction and/or Y direction of the XY plane substantially without part moving in a Z direction, where the Z direction is a height direction with respect to the XY plane.

3. The exposure apparatus of claim 1, wherein the gas sucking device sucks the gas in substantially all directions of the outer edge of the wafer.

4. The exposure apparatus of claim 1, wherein the gas sucking device comprises intake holes placed opposite the outer edge of the wafer.

5. The exposure apparatus claim 1, wherein the gas sucking device is placed to surround the outer edge of the wafer.

6. The exposure apparatus of claim 1, wherein the gas sucking device is placed on the stage in a ring shape to surround the outer edge of the wafer.

7. The exposure apparatus of claim 6, further comprising a chuck placed on the stage to stick the wafer thereto by suction.

8. The exposure apparatus of claim 7, further comprising pins that protrude up through the chuck to support the wafer when the wafer is transferred over the chuck.

9. The exposure apparatus of claim 8, wherein the ends of the pins protrude to be higher than the top surface of the gas sucking device.

10. The exposure apparatus of claim 9, wherein after the wafer is transferred over the chuck, the ends of the pins are positioned lower than the surface of the chuck, so that the wafer is held on the chuck.

11. An exposure method comprising:
mounting a wafer coated with a resist film on a stage; and
projecting exposure light onto the resist film via a projection optical system while sucking gas above the wafer in directions of the outer edge of the wafer

12. The exposure method of claim 11, wherein the wafer is placed on an XY plane, and
wherein the gas is sucked so as to have part moving in an X direction and/or Y direction of the XY plane substantially without part moving in a Z direction, where the Z direction is a height direction with respect to the XY plane.

13. The exposure method of claim 11, wherein the gas is sucked in substantially all directions of the outer edge of the wafer.

14. The exposure method of claim 11, wherein the gas is sucked into intake holes placed opposite the outer edge of the wafer.

15. The exposure method of claim 14, wherein the intake holes are placed to surround the outer edge of the wafer.

16. The exposure method of claim 14, wherein the intake holes are placed over the stage in a ring shape to surround the outer edge of the wafer.

17. The exposure method of claim 11, wherein a chuck placed on the stage sticks the wafer thereto by suction.

18. The exposure method of claim 17, wherein pins protruding up through the chuck, support the wafer when the wafer is transferred over the chuck.

19. The exposure method of claim 18, wherein after the wafer is transferred over the chuck, the ends of the pins are positioned lower than the surface of the chuck.

20. The exposure method of claim 11, wherein the gas above the wafer is outgas emitted from the resist film.
